(19) United States
(12) Patent Application Publication
(10) Pub. No.: US 2026/0313836 A1
(43) Pub. Date: Oct. 8, 2026

(54) SINGLE-PHASE COOLANT SPRAYER

(71) Applicant: AirSys Holding, Inc., Greer, SC (US)

(72) Inventors: Mengyuan Yuan, Anderson, SC (US); Nan Chen, Alpharetta, GA (US); Yunshui Chen, Greer, SC (US)

(21) Appl. No.: 19/391,565

(22) Filed: Nov. 17, 2025

Related U.S. Application Data
(60) Provisional application No. 63/782,795, filed on Apr. 3, 2025.

(51) Int. Cl. H05K 7/20; B22F 10/68; B22F 10/85; B29C 64/141; B29C 64/30; B29C 64/393; B29C 71/00; B29L 31/34; B33Y 10/00; B33Y 40/20; B33Y 50/02; B33Y 80/00

(52) U.S. Cl. CPC H05K 7/20272; B22F 10/68; B22F 10/85; B29C 64/141; B29C 64/30; B29C 64/393; B29C 71/009; B33Y 10/00; B33Y 40/20; B33Y 50/02; B33Y 80/00; B22F 2998/10; B29L 2031/3406

(57) ABSTRACT

A sprayer for spraying a liquid coolant may include a hollow plenum configured to provide a manifold for a pressurized liquid coolant and one or more inlet ports, coupled to the plenum, configured to receive the pressurized liquid coolant. The plenum may include a plurality of reinforcing members, coupled between interior sides of the plenum, configured to add rigidity to the plenum. a plurality of spray orifices on an outside planar surface of the plenum, configured to spray the pressurized liquid coolant onto heat-generating components outside the sprayer proximate to the spray orifices, and a plurality of edge holes, configured to allow material powder from 3D printing to be removed from the plenum by air pressure, further configured to be plugged when the sprayer is spraying the pressurized liquid coolant.

### PRIORITY

This patent application claims priority from Provisional U.S. Patent Application No. 63/782,795, filed Apr. 3, 2025, entitled DISTRIBUTED SERVER RACK COOLING SYSTEM and naming Nan Chen, Mengyuan Yuan, Zhipeng Zhao, and Yunshui Chen as the inventors, the disclosure of which is incorporated herein in its entirety, by reference.

### FIELD

Illustrative embodiments of the invention generally relate to data center server cooling and, more particularly, various embodiments of the invention relate to a single-phase coolant sprayer for efficient data center cooling.

### BACKGROUND

Data centers may include large numbers of computers, data storage, and networking resources. The computers are typically servers, each including one or more very powerful processors and significant memory resources. The servers consume significant amounts of power and produce a large amount of heat, which must be dealt with by the data center.

Data center cooling maintains the right temperatures for servers and associated equipment to prevent overheating and server shutdown and ensure reliable and efficient performance. Formerly, data centers used various forms of air cooling and refrigeration to maintain proper equipment temperatures. However, with dramatic increases in processor and computer operating speeds, traditional air cooling is insufficient. Newer systems use various forms of liquid or oil cooling to maintain equipment temperatures.

### SUMMARY OF VARIOUS EMBODIMENTS

In accordance with one embodiment of the invention, a sprayer for spraying a liquid coolant may include a hollow plenum configured to provide a manifold for a pressurized liquid coolant and one or more inlet ports, coupled to the plenum, configured to receive the pressurized liquid coolant. The plenum may include a plurality of reinforcing members, coupled between interior sides of the plenum, configured to add rigidity to the plenum. a plurality of spray orifices on an outside planar surface of the plenum, configured to spray the pressurized liquid coolant onto heat-generating components outside the sprayer proximate to the spray orifices, and a plurality of edge holes, configured to allow material powder from 3D printing to be removed from the plenum by air pressure, further configured to be plugged when the sprayer is spraying the pressurized liquid coolant.

In accordance with other embodiments, the sprayer may be 3D printed as a single component from one of a powdered polymer or a powdered metal material.

In accordance with other embodiments, the sprayer has a generally planar orientation and is configured to be mounted parallel to a server motherboard. The sprayer may also include one or more sprayer mounts, coupled to one or more external surfaces of the sprayer, configured to rigidly couple the sprayer to one of the server motherboard or a packaging structure associated with the server motherboard.

In accordance with other embodiments, the sprayer may also include a plurality of equal sized lateral parallel members extending away from the plenum on a same side of the sprayer as the plurality of spray orifices, configured to fit between memory modules of a server motherboard, wherein a portion of the plurality of spray orifices are between each pair of adjacent lateral members.

In accordance with other embodiments, the sprayer may also include one or more relief holes through a thickness of the plenum, configured to reduce a weight of the sprayer, wherein edges of the one or more relief holes are sealed by sprayer material from an interior of the plenum.

In accordance with other embodiments, locations of the spray orifices, the lateral parallel members, and the one or more relief holes correspond to a layout of the server motherboard.

In accordance with other embodiments, a diameter of the sprayer orifices may correspond to one or more of a desired spray pattern, a desired spray volume of liquid coolant, and a dispersion of sprayed liquid coolant.

In accordance with other embodiments, the plurality of edge holes are orthogonal to the plurality of spray orifices and disposed on lateral surfaces of the plenum.

In accordance with other embodiments, the one or more inlet ports are configured to be coupled to flexible tubing carrying the liquid coolant.

In accordance with other embodiments, a method of manufacturing a sprayer for spraying a pressurized liquid coolant may include creating a 3D print file corresponding to a server motherboard, 3D printing the sprayer from the 3D print file, and blowing powdered material from an interior of the plenum through the plurality of edge holes. The sprayer may include a hollow plenum configured to provide a manifold for a pressurized liquid coolant. The hollow plenum may include a plurality of reinforcing members, coupled between interior sides of the plenum, configured to add stiffness to the plenum, a plurality of spray orifices on an outside planar surface of the plenum, configured to spray the pressurized liquid coolant onto heat-generating components of the server motherboard proximate to the spray orifices, and a plurality of edge holes, configured to allow material powder from 3D printing to be removed from the plenum by air pressure and further configured to be plugged when the sprayer is spraying the pressurized liquid coolant, and one or more inlet ports, coupled to the plenum, configured to receive the pressurized liquid coolant. The server motherboard may include one or more CPU/GPU heat sinks and one or more memory modules.

In accordance with other embodiments, wherein after blowing powdered material from an interior of the plenum, the method further includes plugging the plurality of edge holes with a plurality of plugs.

In accordance with other embodiments, a non-transitory computer-readable medium stores instructions that, when executed by a processor, causes a 3D printer to manufacture a sprayer for spraying a pressurized liquid coolant. The instructions may include 3D printing the sprayer, where the sprayer includes a hollow plenum configured to provide a manifold for a pressurized liquid coolant and one or more inlet ports, coupled to the plenum, configured to receive the pressurized liquid coolant. The plenum may include one or more reinforcing members, coupled between interior sides of the plenum, configured to add stiffness to the plenum, a plurality of spray orifices on an outside planar surface of the plenum, configured to spray the pressurized liquid coolant onto heat-generating components of a server motherboard proximate to the spray orifices, and a plurality of edge holes, configured to allow material powder from 3D printing to be removed from the plenum by air pressure and further configured to be plugged when the sprayer is spraying the pressurized liquid coolant. The server motherboard includes one or more CPU/GPU heat sinks and one or more memory modules.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a front isometric view of a single-phase coolant sprayer in accordance with illustrative embodiments of the invention.

FIG. 2 schematically shows a rear isometric view of a single-phase coolant sprayer in accordance with illustrative embodiments of the invention.

FIG. 3 schematically shows a side view of a single-phase coolant sprayer in accordance with illustrative embodiments of the invention.

FIG. 4 schematically shows a top view of a single-phase coolant sprayer in accordance with illustrative embodiments of the invention.

FIG. 5 schematically shows a bottom view of a single-phase coolant sprayer in accordance with illustrative embodiments of the invention.

FIG. 6 schematically shows a front isometric view of a representative server motherboard in accordance with illustrative embodiments of the invention.

FIG. 7 schematically shows a front isometric view of a single-phase coolant sprayer attached to a representative server motherboard in accordance with embodiments of the invention.

FIG. 8 schematically a flowchart of a 3D printing fabrication process for the sprayer in accordance with illustrative embodiments of the invention.

### DESCRIPTION OF ILLUSTRATIVE EMBODIMENTS

In illustrative embodiments, a single-phase coolant sprayer for cooling server motherboards and other components in a data center are described. Single-phase coolant sprayers receive a cooled single-phase coolant liquid from a heat exchanger and spray the coolant through orifices to heat sinks and other high temperature components of server motherboards.

Data centers generally includes many server computers organized into groups of racks. Each rack may include any number of servers but typically include 10-30 identical computers in a “blade” format that may be individually added to or removed from a rack. Each rack often includes an associated cooling system to cool very high temperature electronic components, such as central processing units (CPUs) and/or graphical processing units (GPUs). In some cases, other components such as memory modules/devices, northbridge, or southbridge components may be individually cooled as well. Each high-temperature component may have an associated heat sink that is cooled by air, a liquid, or a combination of air and a liquid. Older servers and components produced much less heat than modern components, so air cooling was often sufficient. However, present day individual components may produce over 500 watts of heat, requiring more advanced liquid cooling systems. Illustrative embodiments address this problem with an advanced liquid cooling system for data center applications. Details of various embodiments are discussed below.

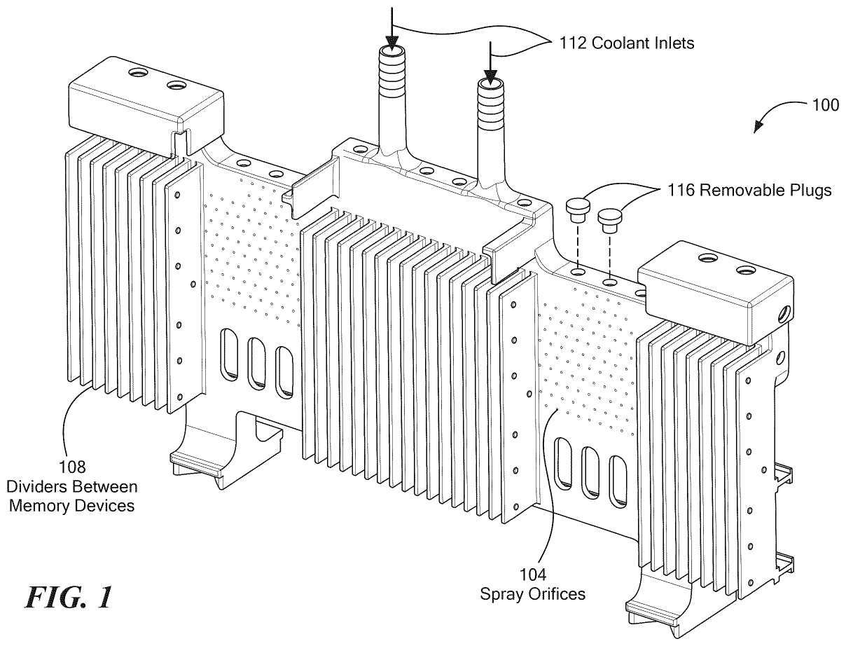

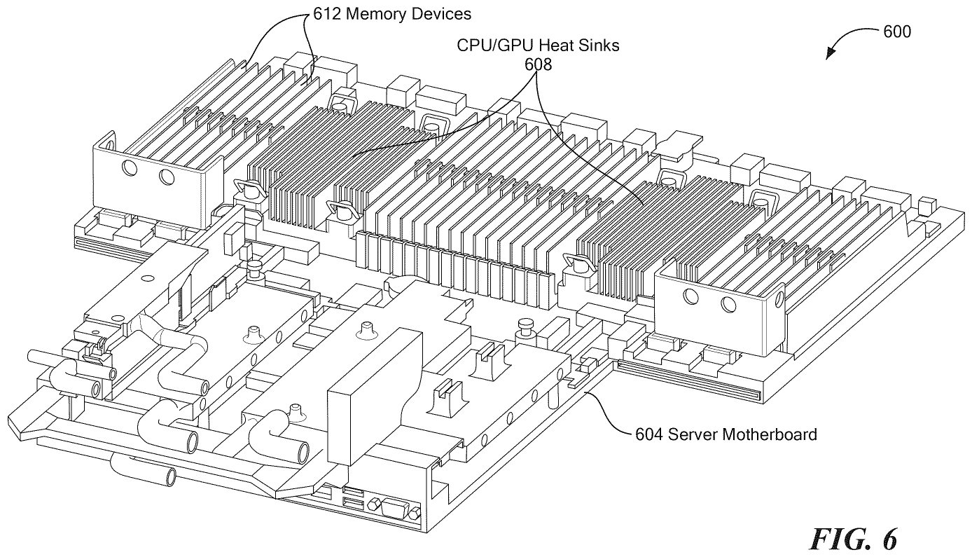

Referring to FIG. 1, a front isometric view of a single-phase coolant sprayer 100 in accordance with illustrative embodiments of the invention is shown. The single phase coolant sprayer 100 sprays cooled liquid coolant onto heat sinks and other components on server motherboards that require active liquid cooling. FIG. 1 illustrates an exemplary sprayer 100 that is optimized for a specific server motherboard (an example is shown in FIG. 6), rather than all or even most server motherboards. The sprayer 100 is created by an additive 3D printing process that builds the sprayer 100 in layers from a bottom upward to a top of the sprayer 100. A 3D printer that performs the 3D printing process controls the build from a 3D print file that is constructed beforehand. The 3D print file instructs the 3D printer where to spray the material (powdered polymer or metal) and not spray the material, with fine delineation. The 3D print file addresses the external dimensions, internal dimensions, thicknesses, built-up areas, voids, and keep outs. Various holes, projections, and other features of the sprayer 100 are included in the 3D print file. 3D printing is very efficient for small production runs since each sprayer 100 is created individually and does not require expensive tooling and scheduled production runs that tie up production equipment. The sprayer 100 may be constructed as a single component rather than multiple components that must be assembled. This reduces manual labor and production time/cost.

Since the sprayer 100 is 3D printed, it may use available space on and around a server motherboard 604 and external chassis packaging. As a result of this, the sprayer 100 may be symmetrical or asymmetrical, have a constant or variable thickness, or any practical shape, depending on space constraints. It may therefore be designed and printed to accommodate existing motherboards and packaging and not require motherboard re-design. The 3D printed sprayer 100 presents a custom cooling solution with faster turnaround, greater flexibility, and low per-unit costs (no tooling, inventory, production run scheduling, etc.) compared to conventional heat sinks and sprayers.

In addition to CPU/GPU heat sinks, other heat-producing components such as northbridge/southbridge controllers may require a heat sink. Preferably, the heat sinks are oriented on the heat-producing components such that when the packaged server is oriented vertically or angled, coolant sprayed to the heat sinks will flow off the heat sinks and flow downward by gravity. Preferably, the server is packaged within an enclosure (e.g., a sheet metal enclosure) that retains the sprayed coolant within the package and provides means to remove the heated coolant from the server, cool it, and pump the cooled coolant back to the sprayer 100. The sprayer 100 includes a number of spray orifices 104 on one generally planar side that direct a controlled volume of spray to heat sinks on the server motherboard. In one embodiment, larger spray orifices 104 are provided for heat sinks requiring a higher volume of liquid coolant and smaller spray orifices 104 are provided for heat sinks or components requiring a lower volume of liquid coolant.

In addition to components with dedicated heat sinks, server motherboards typically include an array of memory modules for data and program storage. The memory modules are generally located in a parallel fashion on the motherboard for efficient layout and near a northbridge controller that controls the memory modules. To provide dedicated cooling for memory modules, the sprayer 100 may include a number of dividers 108 between adjacent memory modules. The dividers 108 keep sprayed liquid coolant between the dividers 108 so that it efficiently cools each memory module and limits overspray to other parts of the packaged server. The dividers 108 are oriented vertically such that the coolant flows between them without pooling against sprayer 100 or motherboard surfaces.

The sprayer 100 may include a number of coolant inlet ports 112. In the illustrated embodiment, there are two coolant inlet ports 112. A greater number of inlet ports 112 may facilitate more equal and consistent distribution of coolant liquid within a larger sprayer 100, especially when a server motherboard requires a physically large and/or wide sprayer 100. In one embodiment, the coolant inlet ports 112 may include quick-disconnect fittings to facilitate fast installation or removal for servicing. In another embodiment, the coolant inlet ports 112 may include a stepped profile to facilitate use with flexible coolant hoses (e.g., rubber hoses).

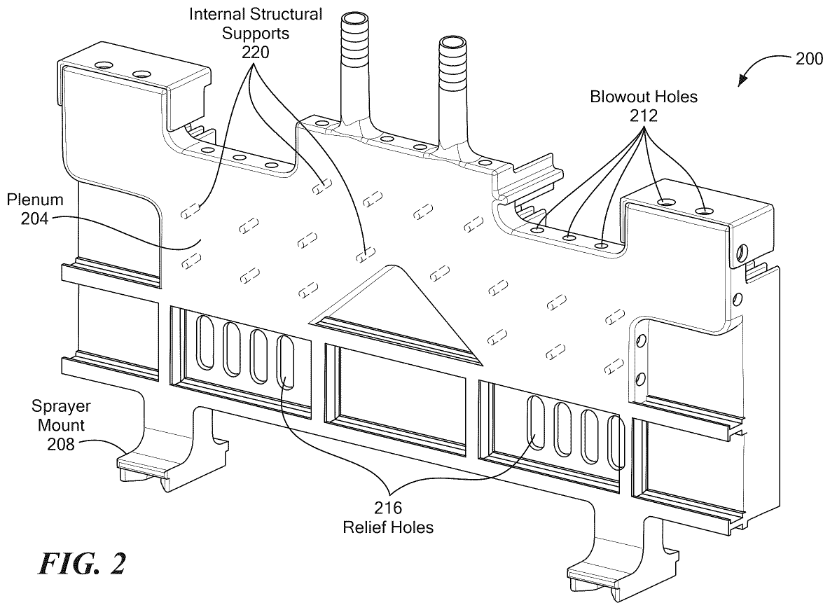

Although not part of a 3D printing operation, in use the sprayer 100 may also include a number of removable plugs 116 that are used as described with reference to FIG. 2.

Referring to FIG. 2, a rear isometric view of a single-phase coolant sprayer 200 in accordance with illustrative embodiments of the invention is shown. The rear view is the side of the sprayer 100 that faces away from the server motherboard. For most sprayers 100, the spray orifices 104 are only located on the front side. However, recognizing the possibility that more complex arrangements of server motherboards are possible, for example in cases where heat sinks and components that require liquid cooling are located on both sides of the sprayer 100, spray orifices 104 (and possibly dividers between memory devices 108, as well) may be located on both planar sides of the sprayer 100.

FIG. 2 shows a plenum 204, which is an enclosed hollow space that temporarily stores the liquid coolant. The plenum 204 may have a number of relieved areas, cutouts, projections, and shapes to accommodate specific requirements of the server motherboard and packaging.

In use with the liquid coolant, the inputs to the plenum are the coolant inlet ports 112 and the outputs are the spray orifices 104. Also visible are a pair of sprayer mounts 208, which secure the sprayer 100 to the server motherboard or (in this case) to a portion of the sheet metal of the packaged server. The sprayer mounts 208 maintain a fixed relationship between the sprayer 100 and the server motherboard to allow consistent application of the liquid coolant to the heat sinks and other components. Although sprayer mounts 208 having a “foot” orientation are shown, any type and number of projections, arms, brackets, or other supports may be used. Preferably, the sprayer mounts 208 do not require separate fasteners such as screws, washers, and nuts, although such fasteners may be required for some embodiments. In the illustrated embodiment, the sprayer mounts 208 are 3D printed and part of the sprayer 100 as formed.

In the illustrated embodiment, the sprayer 100 includes a number of blowout holes 212 on the periphery of lateral surfaces of the sprayer 100. In other embodiments, blowout holes 212 may be located on the front and/or rear planar surfaces of the sprayer 100, as well. Blowout holes 212 are included as part of the 3D printing process. They are plugged by the removable plugs 116 shown in FIG. 1 when the sprayer 100 is mounted and in use but may be required to complete the manufacturing operation of the sprayer 100.

The 3D printing process uses a powdered plastic/polymer or metal material which is fused together. However, routinely some of the powdered material is not fused, and may remain within the sprayer 100 in powdered form after 3D printing is completed. The residual powdered material must be removed from the plenum 204 so that it does not clog the spray orifices 104. The blowout holes 212 allow the residual powdered material to be removed from the plenum 204 by blowing high pressure air though the blowout holes 212. It is desirable to have blowout holes 212 at regular spacing so that the high pressure air can reach all locations within the plenum 204 and cause the powdered material to exit the plenum 204. In one embodiment, some blowout holes 212 may be plugged during the blowout process to increase air velocity through harder to reach locations within the plenum 204.

In one embodiment, the plenum 204 may include a number of relief holes 216. Relief holes 216 pass completely through the width of the sprayer 100 and sides of the relief holes 216 are sealed with the sprayer 100 material. The relief holes 216 reduce the amount of material needed to form the sprayer 100, reduce the weight of the sprayer 100, and allow air (fans, etc) to pass therethrough. The sprayer 100 may include any number, size, and location of relief holes 216, although relief holes 216 should not be located where spray orifices 104 or dividers 108 need to be located.

The view of FIG. 2 also shows a number of internal structural supports 220 within the plenum 204. The internal structural supports 220 couple the interior of the planar sides together, making the sprayer 100 more rigid. The number, location, and spacing of the internal structural supports 220 is design-dependent and may differ between sprayers 100 for different server motherboards.

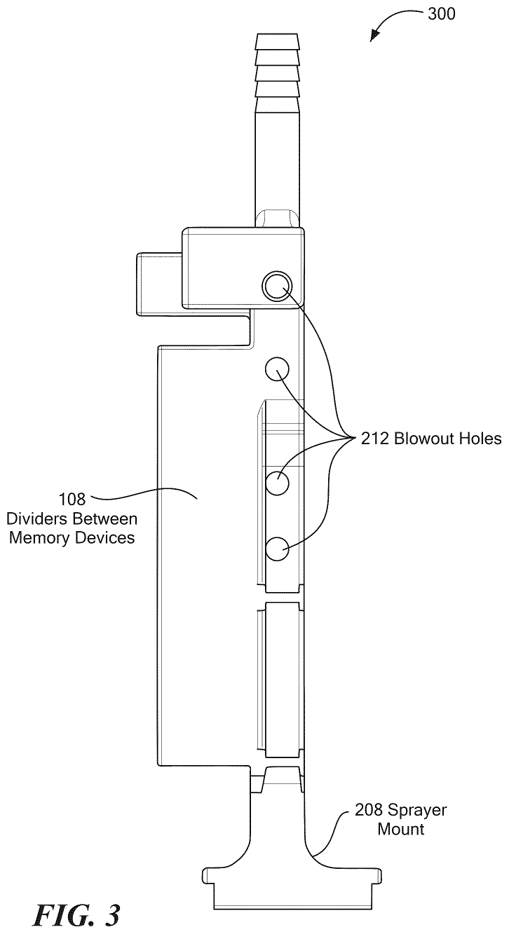

Referring to FIG. 3, a side view of a single-phase coolant sprayer 300 in accordance with illustrative embodiments of the invention is shown. The side view 300 illustrates a sprayer mount 208, dividers between memory devices 108, and a number of blowout holes 212. In the illustrated embodiment, the spray orifices 104 are oriented facing to the left.

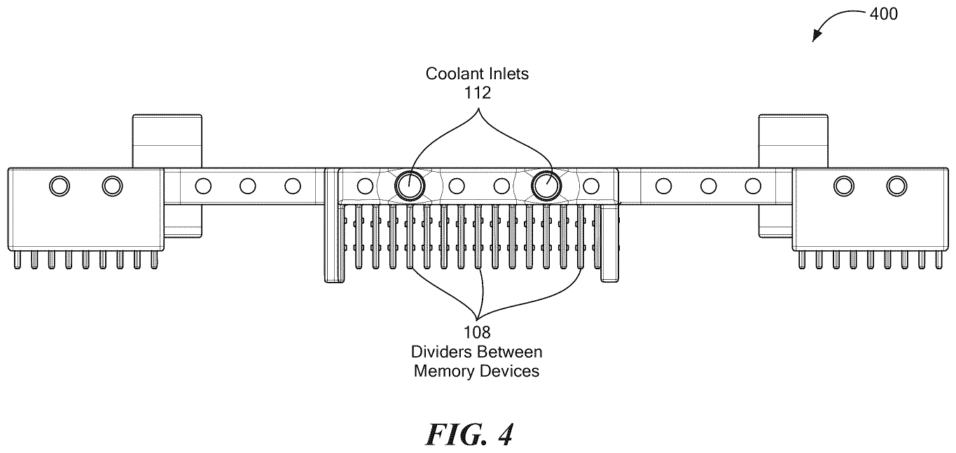

Referring to FIG. 4, a top view of a single-phase coolant sprayer 400 in accordance with illustrative embodiments of the invention is shown. The top view illustrates the spacing between the dividers 108, the coolant inlets 112, and the blowout holes 212.

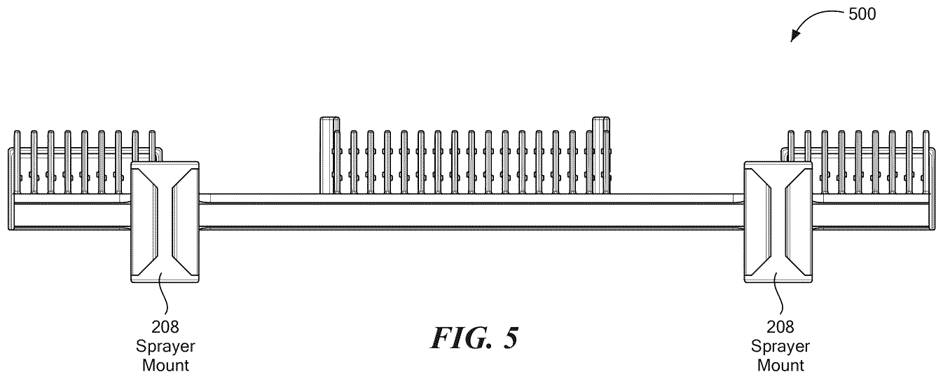

Referring to FIG. 5, a bottom view of a single-phase coolant sprayer 500 in accordance with illustrative embodiments of the invention is shown. The bottom view illustrates the spacing between the dividers 108 and the sprayer mounts 208.

Referring to FIG. 6, a front isometric view of a representative server motherboard 600 in accordance with embodiments of the invention is shown. FIG. 6 illustrates a representative server motherboard 604 that corresponds with the server 100 shown throughout the present application. A pair of CPU/GPU heat sinks 608 are shown along with many parallel memory devices 612. The memory devices 612 (SIMMs, DIMMs, etc) are configured to fit between the dividers 108. Other unnamed components are shown. Those that require liquid spray cooling may have one or more spray orifices 104 of the sprayer 100 assigned and configured to provide sprayed liquid coolant.

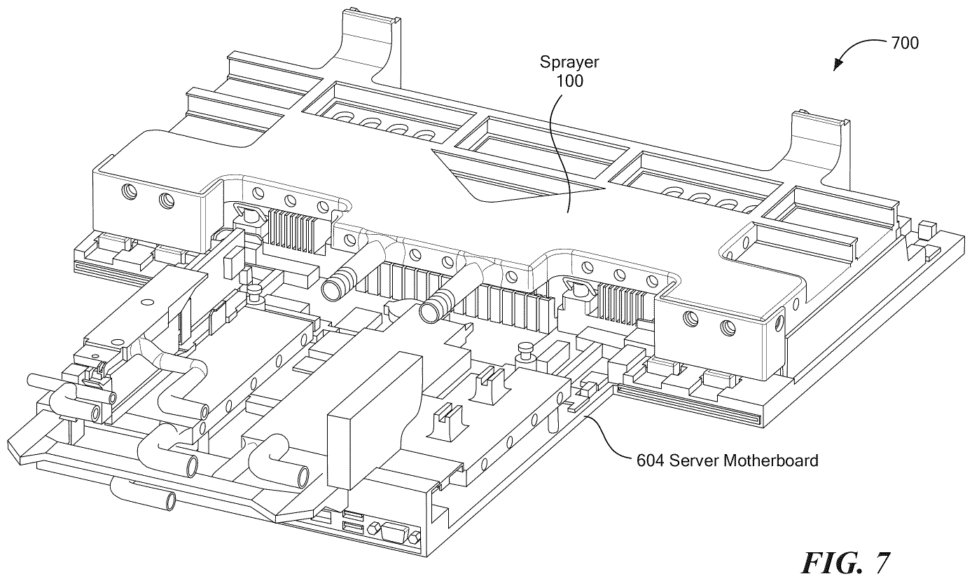

Referring to FIG. 7, a front isometric view of a single-phase coolant sprayer attached to a representative server motherboard 700 in accordance with illustrative embodiments of the invention is shown. FIG. 7 illustrates the server motherboard 604 of FIG. 6 with the sprayer 100 attached. The perspective of FIG. 7 is from the top of a vertical packaged server, with the two coolant inlets 112 in the center intended to face generally upward. The sprayer 100 coupled to the server motherboard 604 provides a compact envelope and fits within the low-profile packaging for a complete server.

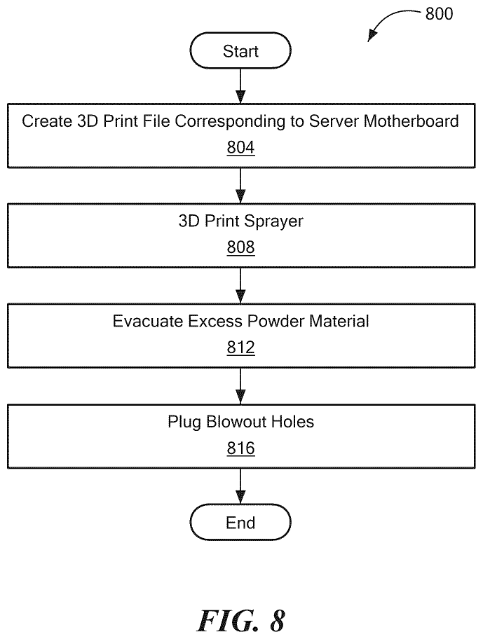

Referring to FIG. 8, a flowchart of a 3D printing fabrication process 800 for the sprayer in accordance with illustrative embodiments of the invention is shown. Flow begins at block 804.

At block 804, a 3D print file is created. The 3D print file corresponds to a specific server motherboard 604 layout. Flow proceeds to block 808.

At block 808, a 3D printer prints the sprayer 100 from the 3D print file. Flow proceeds to block 812.

At block 812, excess powder material is evacuated from the interior of the plenum 204. High pressure air is blown into one or more blowout holes 212 or one or more inlet ports 112. Flow proceeds to block 816.

At block 816, the sprayer 3D printing process is completed. The blowout holes 212 are plugged. In one embodiment, the blowout holes 212 are plugged with a removable plug 116 such as a rubber or polymer plug that fit the blowout holes 212. In another embodiment, the blowout holes 212 may be permanently plugged using an epoxy or other glue. Flow ends at block 816.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A sprayer for spraying a liquid coolant, comprising:
a hollow plenum configured to provide a manifold for a pressurized liquid coolant, comprising:
a plurality of reinforcing members, coupled between interior sides of the plenum, configured to add rigidity to the plenum;
a plurality of spray orifices on an outside planar surface of the plenum, configured to spray the pressurized liquid coolant onto heat-generating components outside the sprayer proximate to the spray orifices; and
a plurality of edge holes, configured to allow material powder from 3D printing to be removed from the plenum by air pressure, further configured to be plugged when the sprayer is spraying the pressurized liquid coolant; and
one or more inlet ports, coupled to the plenum, configured to receive the pressurized liquid coolant.

2. The sprayer of claim 1, wherein the sprayer is 3D printed as a single component from one of a powdered polymer or a powdered metal material.

3. The sprayer of claim 2, wherein the sprayer has a generally planar orientation and is configured to be mounted parallel to a server motherboard, the sprayer further comprising:
one or more sprayer mounts, coupled to one or more external surfaces of the sprayer, configured to rigidly couple the sprayer to one of the server motherboard or a packaging structure associated with the server motherboard.

4. The sprayer of claim 2, further comprising:
a plurality of equal sized lateral parallel members extending away from the plenum on a same side of the sprayer as the plurality of spray orifices, configured to fit between memory modules of a server motherboard, wherein a portion of the plurality of spray orifices are between each pair of adjacent lateral members.

5. The sprayer of claim 4, further comprising:
one or more relief holes through a thickness of the plenum, configured to reduce a weight of the sprayer, wherein edges of the one or more relief holes are sealed by sprayer material from an interior of the plenum.

6. The sprayer of claim 5, wherein locations of the spray orifices, the lateral parallel members, and the one or more relief holes correspond to a layout of the server motherboard.

7. The sprayer of claim 2, wherein a diameter of the sprayer orifices corresponds to one or more of a desired spray pattern, a desired spray volume of liquid coolant, and a dispersion of sprayed liquid coolant.

8. The sprayer of claim 2, wherein the plurality of edge holes are orthogonal to the plurality of spray orifices and disposed on lateral surfaces of the plenum.

9. The sprayer of claim 2, wherein the one or more inlet ports are configured to be coupled to flexible tubing carrying the liquid coolant.

10. A method of manufacturing a sprayer for spraying a pressurized liquid coolant, comprising:
creating a 3D print file corresponding to a server motherboard, the server motherboard comprising one or more CPU/GPU heat sinks and one or more memory modules;
3D printing the sprayer from the 3D print file, the sprayer comprising:
a hollow plenum configured to provide a manifold for a pressurized liquid coolant, comprising:
a plurality of reinforcing members, coupled between interior sides of the plenum, configured to add stiffness to the plenum;
a plurality of spray orifices on an outside planar surface of the plenum, configured to spray the pressurized liquid coolant onto heat-generating components of the server motherboard proximate to the spray orifices; and
a plurality of edge holes, configured to allow material powder from 3D printing to be removed from the plenum by air pressure, further configured to be plugged when the sprayer is spraying the pressurized liquid coolant; and
one or more inlet ports, coupled to the plenum, configured to receive the pressurized liquid coolant; and
blowing powdered material from an interior of the plenum through the plurality of edge holes.

11. The method of claim 10, wherein after blowing powdered material from an interior of the plenum, the method further comprising:
plugging the plurality of edge holes with a plurality of plugs.

12. The method of claim 10, wherein the sprayer is 3D printed as a single component from one of a powdered polymer or a powdered metal material.

13. The method of claim 12, wherein the sprayer further comprises a plurality of equal sized lateral parallel members extending away from the plenum on a same side of the sprayer as the plurality of spray orifices, configured to fit between memory modules of a server motherboard, wherein a portion of the plurality of spray orifices are between each pair of adjacent lateral members.

14. The method of claim 13, wherein the sprayer further comprises one or more relief holes through a thickness of the plenum, configured to reduce a weight of the sprayer, wherein edges of the one or more relief holes are sealed by sprayer material from an interior of the plenum.

15. The method of claim 14, wherein locations of the spray orifices, the lateral parallel members, and the one or more relief holes identified in the 3D print file corresponds to a layout of the server motherboard.

16. The method of claim 12, wherein a diameter of the sprayer orifices corresponds to one or more of a desired spray pattern, a desired spray volume of liquid coolant, and a dispersion of sprayed liquid coolant.

17. The method of claim 12, wherein the plurality of edge holes are orthogonal to the plurality of spray orifices and disposed on lateral surfaces of the plenum.

18. The system of claim 12, wherein the one or more inlet ports are configured to be coupled to flexible tubing carrying the liquid coolant.

19. A non-transitory computer-readable medium storing instructions that, when executed by a processor, cause a 3D printer to manufacture a sprayer for spraying a pressurized liquid coolant, the instructions comprising:
3D printing the sprayer, the sprayer comprising:
a hollow plenum configured to provide a manifold for a pressurized liquid coolant, the plenum comprising:
one or more reinforcing members, coupled between interior sides of the plenum, configured to add stiffness to the plenum;
a plurality of spray orifices on an outside planar surface of the plenum, configured to spray the pressurized liquid coolant onto heat-generating components of a server motherboard proximate to the spray orifices, the server motherboard comprising one or more CPU/GPU heat sinks and one or more memory modules;
a plurality of edge holes, configured to allow material powder from 3D printing to be removed from the plenum by air pressure, and further configured to be plugged when the sprayer is spraying the pressurized liquid coolant; and
one or more inlet ports, coupled to the plenum, configured to receive the pressurized liquid coolant.

20. The non-transitory computer-readable medium of claim 19, wherein the sprayer is 3D printed as a single component from one of a powdered polymer or a powdered metal material.
